(19) United States
(12) Patent Application Publication
(10) Pub. No.: US 2012/0160315 A1
(43) Pub. Date: Jun. 28, 2012

(54) THIN FILM SOLAR CELL MODULE AND MANUFACTURING METHOD THEREOF

(75) Inventors: Sunho KIM, Seoul (KR); Heonmin Lee, Seoul (KR); Jinhee Park, Seoul (KR); Jinhyung Jun, Seoul (KR); Sehwon Ahn, Seoul (KR); Dongjoo You, Seoul (KR)

(73) Assignee: LG ELECTRONICS INC., Seoul (KR)

(21) Appl. No.: 13/174,431

(22) Filed: Jun. 30, 2011

(30) Foreign Application Priority Data
Dec. 22, 2010 (KR) 10-2010-0132767

(51) Int. Cl. H01L 31/0224; H01L 31/18

(52) U.S. Cl. 136/256; 438/98; 257/E31.126

(57) ABSTRACT

Discussed are a thin film solar cell module and a method of fabricating the same. A solar cell module includes a substrate; and a transparent electrode layer. The transparent electrode layer in turn includes a first electrode layer provided on the substrate; and a second electrode layer provided on the first electrode layer, wherein the first electrode layer and the second electrode layer are made of different materials and the second electrode layer is locally formed on portions of the first electrode layer. Accordingly, the transparent electrode layer exhibits improved transmittance of monochromatic light as well as increased light scattering, thereby enhancing efficiency of the thin film solar cell module.

### CROSS-REFERENCE TO RELATED APPLICATION

This application claims priority to and the benefit of Korean Application No. 10-2010-0132767, filed on Dec. 22, 2010 in the Korean Intellectual Property Office, the disclosure of which is incorporated herein by reference.

### BACKGROUND OF THE INVENTION

1. Field of the invention

Embodiments of the present invention relate to a thin film solar cell module and a method for manufacturing the same and more particularly, example embodiments of the present invention relate to a thin film solar cell module having a transparent electrode layer, in which a plurality of islands are formed, and a method of fabricating the same.

2. Description of the Related Art

Since exhaustion of existing energy resources such as oil and coal is expected to occur soon, alternative energy sources to replace such non-renewable energy sources have recently attracted a great deal of interest. Among various types of alternative energy sources, a solar cell which uses a semiconductor device to directly convert solar energy into electric energy has come into the spotlight as a next-generation alternative energy source.

A solar cell refers to a device utilizing photovoltaic effects to convert solar energy into electricity, and may be classified into a silicon solar cell, a thin film type solar cell, a dye-sensitized solar cell, an organic polymer solar cell (or an organic solar cell), or the like, in terms of constitutional materials. In such solar cells, it is very important to improve conversion efficiency, which is a ratio of incident solar radiation to electricity output.

Among various solar cells, although a thin film solar cell has attracted a lot of interest as a technology capable of providing a large area solar cell module at low cost, the conversion efficiency thereof may be slightly low, as compared to a silicon solar cell. Therefore, in order to enhance the conversion efficiency of the thin film solar cell, a groove structure may be formed by etching a transparent electrode layer provided on a substrate, on which solar radiation is incident, and the groove structure may efficiently extend an optical path, thus improving solar absorption.

However, tin oxide (SnO₂), which is a general material utilized as for a transparent electrode layer, provides only small scale reliefs or grooves and cannot increase light scattering, thus having difficulty in extending the optical path. Further, if a thickness of the thin film to be deposited is increased to enlarge a relief (or groove), defects such as cracks may occur on the thin film due to collision in a growth direction, and in turn, deteriorating quality.

FIG. 1 illustrates measured results of light transmittances of transparent electrode layers made of tin oxide and zinc oxide, respectively. Referring to FIG. 1, it can be seen that the transparent electrode layer made of tin oxide has a higher light transmittance, in particular, at a bandwidth of 300 to 400 nm, than the transparent electrode layer made of zinc oxide. That is, as another material used for fabricating a transparent electrode, zinc oxide (ZnO) has a demerit of decreased transmittance of monochromatic light owing to inherent material characteristics, although this material is advantageous in controlling groove shapes to enhance light scattering.

### SUMMARY OF THE INVENTION

Therefore, an object of the present invention is to provide a thin film solar cell module having a transparent electrode layer, which can improve transmittance of monochromatic light and light scattering, and a method of fabricating the same.

In order to accomplish the foregoing and other objectives, according to an example embodiment of the present invention, there is provided a thin film solar cell module including a substrate and a transparent electrode layer provided on the substrate, and the transparent electrode layer includes: a first electrode layer provided on the substrate; and a second electrode layer provided on the first electrode layer, the first electrode layer and the second electrode layer being made of different materials and the second electrode layer being locally formed on portions of the first electrode layer.

The second electrode layer is formed of a plurality of islands on the first electrode layer, and portions of a top side of the first electrode layer may be exposed between the plural islands.

The first electrode layer may be made of tin oxide while the second electrode layer may be made of zinc oxide.

A distance between two of the plural islands may range from 0.5 to 3 μm.

A thickness of the first electrode layer may range from 100 to 800 nm.

Moreover, a protective layer may be provided on the first electrode layer between the plural islands.

Here, the protective layer may be formed using zinc oxide.

The transparent electrode layer may further include a photoelectric conversion layer, a rear electrode layer, a seal film and a rear substrate sequentially arranged thereon.

In order to accomplish the foregoing and other objectives, according to an example embodiment of the present invention, there is provided a method of fabricating a thin film solar cell module including forming a transparent electrode layer on a substrate, and the forming of the transparent electrode layer may include: providing a first electrode layer on the substrate; providing a second electrode layer on the first electrode layer; and etching the second electrode layer, wherein the first electrode layer and the second electrode layer are formed using different materials and the second electrode layer may be locally formed on portions of the first electrode layer by etching.

The second electrode layer is formed of a plurality of islands, and portions of a top of the first electrode layer may be exposed between the plural islands.

The second electrode layer may have a thickness of 100 to 800 nm.

The first electrode layer may be formed of tin oxide.

The second electrode layer may be formed of zinc oxide.

The etching may include wet etching of the second electrode layer using an acid.

Among the plural islands, a distance between two neighboring islands may range from 0.5 to 3 μm.

The foregoing method may further include foaming a protective layer on top of the first electrode layer between the plural islands.

### BRIEF DESCRIPTION OF THE DRAWINGS

The above and other objects, features and other advantages of the embodiments of the present invention will be more clearly understood from the following detailed description taken in conjunction with the accompanying drawings, in which:

FIG. 1 illustrates measured results of light transmittances of transparent electrode layers made of tin oxide and zinc oxide, respectively;

FIG. 2 is a cross-sectional view showing a cross section of a thin film solar cell module according to an example embodiment of the present invention;

FIG. 3 is an enlarged view illustrating part A shown in FIG. 2; and

FIGS. 4 through 6 relate to a method of fabricating a thin film solar cell module according to an example embodiment of the present invention.

### DETAILED DESCRIPTION OF THE EMBODIMENTS

From the following drawings, respective components may be enlarged, omitted or schematically illustrated for convenience of explanation or clarity. In addition, sizes and areas of respective elements may not entirely reflect real sizes and areas thereof.

Hereinafter, embodiments of the present invention will be described below with reference to the attached drawings.

FIG. 2 is a cross-sectional view illustrating a cross section of a thin film solar cell module according to an example embodiment of the present invention, and FIG. 3 is an enlarged view illustrating part A shown in FIG. 2.

First, referring to FIG. 2, a thin film solar cell module 100 according to the foregoing embodiment may include a substrate 110, a transparent electrode layer 120 provided on the substrate 110, and a photoelectric conversion layer 130, a rear electrode layer 140, a seal film 150 and a rear substrate 160 sequentially arranged on the transparent electrode layer 120.

The substrate 110 may be formed using a transparent material, such as a glass material to pass light, such as solar radiation therethrough, and preferably, but not necessarily, using reinforced glass to protect the photoelectric conversion layer 130 against external impact. In addition, in order to reduce or prevent reflection of solar radiation while increasing light transmittance, a low iron reinforced glass having low-iron content may be preferably used.

The transparent electrode layer 120 functions as a channel, through which current generated in the photoelectric conversion layer 130 flows, and may include a first electrode layer 122 and a second electrode layer 124.

The transparent electrode layer 120 may be formed by doping the transparent electrode layer 120 with impurities of at least one selected from aluminum (Al), gallium (Ga), fluorine (F), germanium (Ge), magnesium (Mg), boron (B), indium (In), tin (Sn) and lithium (Li). Doping of such impurities may be performed by any method of doping metal or other components, such as chemical doping, electrochemical doping, ion implantation, or the like, although the doping method is not particularly limited thereto.

The first electrode layer 122 and the second electrode layer 124 may be formed using different materials. For example, the first electrode layer 122 may be formed by depositing tin oxide having superior light transmittance. Moreover, a top of the first electrode layer 122 may become smooth and flat.

Meanwhile, FIG. 3 is an enlarged view illustrating part A shown in FIG. 2, in a larger scale, and referring to FIG. 3, a thickness (T₁) of the first electrode layer 122 may range from 100 to 800 nm. If the thickness T₁ is less than 100 nm, resistivity of the transparent electrode layer 120 may be increased. On the other hand, if the thickness T₁ of the first electrode layer exceeds 800 nm, collision may occur in a growth direction of tin oxide forming the first electrode layer 122 during deposition, thus causing defects such as cracks. Therefore, the thickness of the first electrode layer 122 preferably, but not necessarily, ranges from 100 to 800 nm.

Also, as described below, the second electrode layer 124 may be formed using, for example, zinc oxide, to form a thin layer and then etching the formed thin layer. In this instance, the etching may be executed to expose a top side of the first electrode layer 122, to thereby partially (or locally) form the second electrode layer 124 on the first electrode layer 122. As a result, the second electrode layer 124 may have a plurality of islands (or plural islands) spaced from one another formed thereon. In embodiments of the present invention, the plural islands of the second electrode layer 124 may be discontinuous portions, which may be distributed evenly or regularly on a surface of the first electrode layer 122. In other embodiments, the plural islands may be distributed unevenly or randomly on the surface of the first electrode layer 122. Additionally, shapes of the plural islands may vary, and may be various polyhedrons, such as a pyramidal structure, or other three dimensional structure such as an ellipsoid.

Accordingly, the second electrode layer 124 may include the plurality of islands, and the plural islands may be located apart from one another on the first electrode layer 122, wherein a distance D₁ between two neighboring islands may range from 0.5 to 3 μm.

As described above, since tin oxide forming the first electrode layer 122 has superior light transmittance and the distance D₁ between two neighboring islands is not less than 0.5 μm, light transmittance of the transparent electrode 120 may be maintained or increased. If the distance D₁ between two neighboring islands is greater than 3 μm, light scattered by the second electrode layer 124 is decreased and, therefore, light absorption through irregular diffusion of incident light may be reduced. Accordingly, in consideration of light transmittance and scattering features, the distance D₁ between two neighboring islands preferably, but not necessarily, ranges from 0.5 to 3 μm.

Therefore, the transparent electrode layer 120 according to the embodiment of the present invention may have enhanced transmittance of monochromatic light because of the first electrode layer 122 exposed between the plural islands and is enabled with an increase in light scattering because of the second electrode layer 124 having a plurality of islands. As a result, light scattering and light transmittance may be improved, thereby enhancing efficiency of a thin film solar cell module 100 including the foregoing transparent electrode layer 120.

A protective layer may be additionally provided on the first electrode layer 122 exposed between the plural islands. In consideration of low anti-plasma characteristics of tin oxide used for forming the first electrode layer 122, the aforementioned protective layer may be formed to protect the exposed first electrode layer 122 under specific process conditions for fabricating a photoelectric conversion layer 130 or the like on the transparent electrode layer 120.

The protective layer may be prepared using, for example, zinc oxide. As described above, since zinc oxide has a lower transmittance of monochromatic light than tin oxide, a thickness of the formed protective layer may not exceed several tens of nanometers, in consideration of light transmittance.

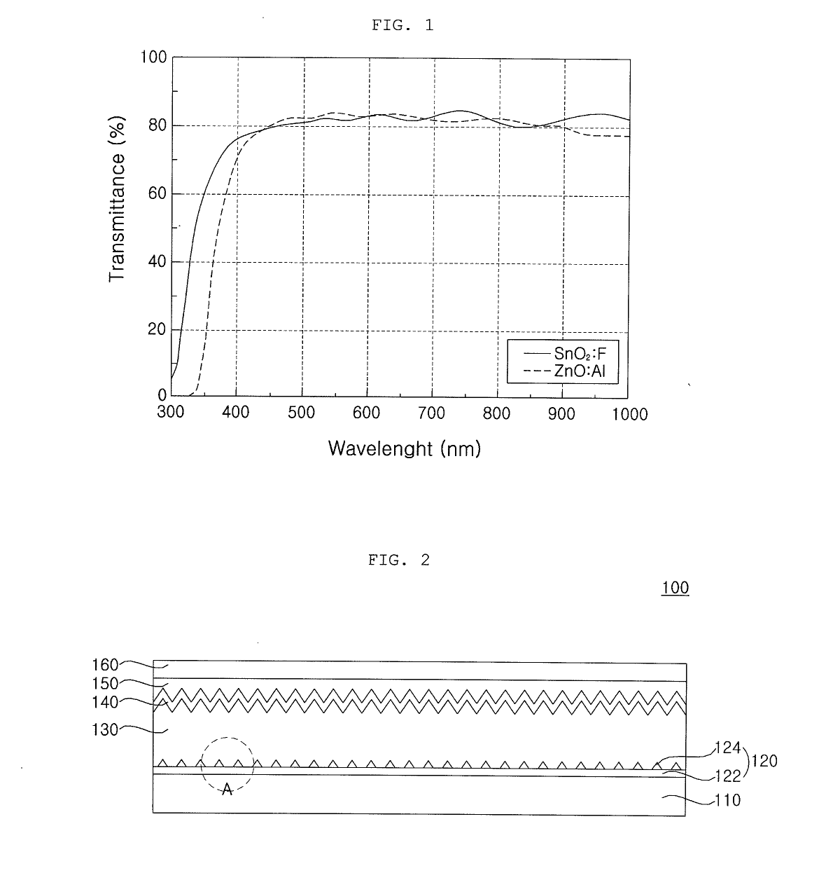

Referring back to FIG. 1, the photoelectric conversion layer 130 on the transparent electrode layer 120 has a P-N junction, thus generating electricity (e.g., electron-hole pairs) by use of the photovoltaic effect based on photoelectric conversion when light is incident of the photoelectric conversion layer 130. For example, the photoelectric conversion layer 130 may comprise amorphous silicon (a-Si), microcrystalline silicon (μc-Si), a compound semiconductor, a tandem shape, or the like, without being particularly limited thereto.

A rear electrode layer 140 may be present on the photoelectric conversion layer 130 to transfer current generated in the photoelectric conversion layer 130 to the outside in cooperation with the transparent electrode layer 120. The rear electrode layer 140 may be made of a transparent material, a translucent material, or an opaque metal material.

Moreover, when the rear electrode layer 140 is made of a metal material having a high light reflectivity, this may reflect the light transmitted through the photoelectric conversion layer 130 back towards the photoelectric conversion layer 130. As a result, a conversion efficiency of the photoelectric conversion layer 130 may be enhanced.

A seal film 150 and a rear substrate 160 may be sequentially arranged on the rear electrode layer 140. The seal film 150 is used to shield external moisture or oxygen while adhering the rear substrate 160 to the rear electrode layer 140. Such a seal film 150 may comprise an ethylenevinyl acetate (EVA) copolymer resin, polyvinyl butyral, ethylenevinyl acetate partial oxide, a silicone resin, an ester resin, an olefin resin, or the like.

The rear substrate 160 has various functions such as water-repellency, insulation and UV shielding, and may be a TPT (Tedlar/PET/Tedlar) type, without being particularly limited thereto. Moreover, the rear substrate 160 is preferably, but not necessarily, made of a material having a high reflectivity in order to reflect and re-use solar radiation incident upon the foregoing substrate 110, or otherwise, may be formed using a transparent material upon which solar radiation is incident.

Although the photoelectric conversion layer 130, the rear electrode layer 140, and the seal film 150 is shown as having respective uneven structures in FIG. 2, each of the photoelectric conversion layer 130, the rear electrode layer 140, and the seal film 150 may or may not have the uneven structures.

FIGS. 4 through 6 relate to a method of fabricating a thin film solar cell module according to an example embodiment of the present invention.

Referring to FIGS. 4 through 6, the method of fabricating a thin film solar cell module according to the foregoing embodiment of the present invention will be described in detail. First, as shown in FIG. 4, a first electrode layer 122 and a second electrode layer 124 are formed on a substrate 110 through deposition. The first electrode layer 122 may be formed by depositing tin oxide while the second electrode layer 124 may be formed by depositing zinc oxide.

The first electrode layer 122 and the second electrode layer 124 may be formed by any conventional deposition method including, for example; chemical vapor deposition (CVD), metal organic chemical vapor deposition (MOCVD), molecular beam epitaxy (MBE), metal organic molecular beam epitaxy (MOMBE), pulsed laser deposition (PLP), atomic layer deposition (ALD), sputtering, RF magnetron sputtering, or the like. In this instance, the first electrode layer 122 may be formed to a thickness of 100 to 800 nm, as described above.

Meanwhile, a thickness T₂ of the second electrode layer 124 may also range from 100 to 800 nm. If the thickness T₂ of the second electrode layer 124 to be deposited is less than 100 nm, it is difficult to control a shape of the plural islands formed by etching the second electrode layer 124, in turn causing a problem in forming a groove shape advantageous to light scattering. On the other hand, if the thickness T₂ of the second electrode layer 124 to be deposited exceeds 800 nm, transmittance of monochromatic light may be decreased.

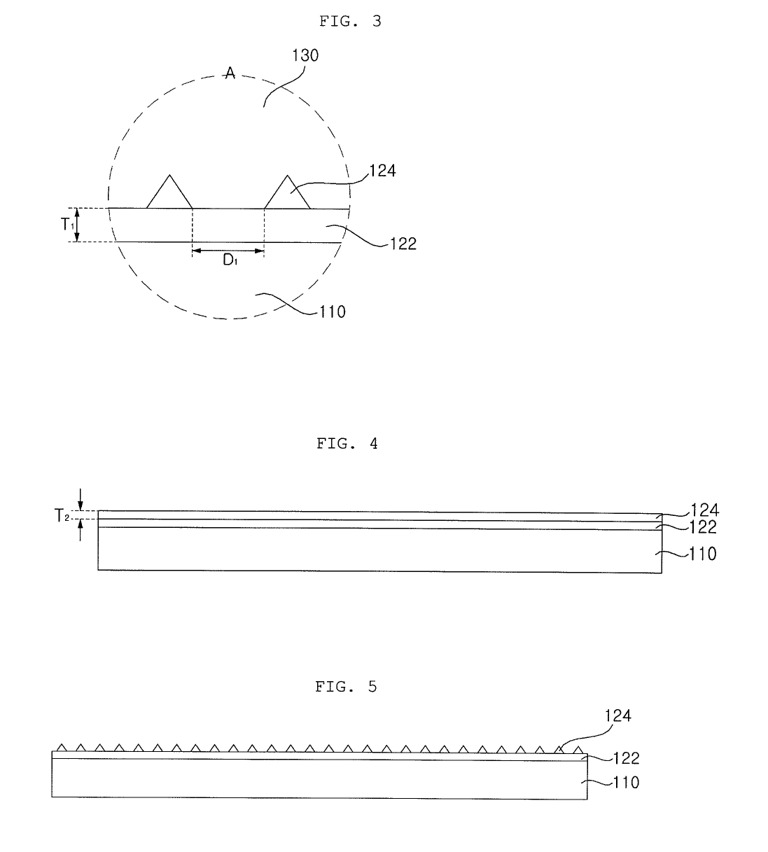

Next, as illustrated in FIG. 5, by etching the second electrode layer 124, a plurality of islands are provided.

The etching of the second electrode layer 124 may be performed by wet etching using acids, preferably, but not necessarily, a strong acid such as hydrochloric acid (HCl). Other etching methods or etchants may be used.

When the second electrode layer 124 is etched using acids, etching proceeds along a crystalline face to form grooves inclined at an angle of 5 to 45° and, if the etching is continued, a thickness of the second electrode layer 124 is decreased and the first electrode layer 122 is exposed. Since the first electrode layer 122 made of tin oxide is not etched by an acid based etching solution or etchant, a plurality of islands may be formed to be spaced from one another on the first electrode layer 122.

In this regard, a distance between two neighboring islands among the plural islands may range from 0.5 to 3 μm, as previously described. If the distance between two neighboring islands is less than 0.5 μm, light transmittance of monochromatic light may be decreased. On the other hand, when the distance between two neighboring islands is greater than 8 μm, light scattering may be reduced.

Since the fabricated transparent electrode layer 120 as described above exhibits a light transmittance of monochromatic light improved by the first electrode layer 122 exposed between the plural islands, as well as light scattering increased by the second electrode layer 124 formed above the first electrode layer 122, a thin film solar cell module having the foregoing transparent electrode layer 120 may exhibit enhanced efficiency based on the improved scattering and light transmittance.

Meanwhile, a protective layer may be provided on a top side of the first electrode layer exposed between the plural islands, in order to protect the exposed first electrode layer 122 in further processes. The protective layer may be formed using, for example, zinc oxide. Also, in consideration of light transmittance, a thickness of the protective layer is preferably, but not necessarily, not more than several tens of nanometers.

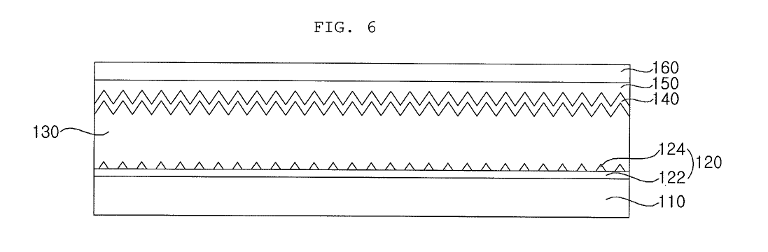

Following this, as shown in FIG. 6, the transparent electrode layer 120 may further include a photoelectric conversion layer 130, a rear electrode layer 140, a seal film 150 and a rear substrate 160 sequentially laminated thereon, thereby completing the solar cell module 100.

In embodiments of the present invention, monochromatic light may refer to light in a predetermined wavelength band or range, and such a band or range may be 100 nm or less.

According to an embodiment of the present invention, a transparent electrode layer includes a first electrode layer made of tin oxide and a plurality of islands made of zinc oxide formed on the first electrode layer to improve light transmittance of monochromatic light and light scattering, thereby enhancing efficiency of a thin film solar cell module having the transparent electrode layer.

While the present invention has been particularly shown and described with reference to example embodiments thereof, these embodiments are only proposed for illustrative purposes and do not limit the present invention. It will be apparent to those skilled in the art that a variety of modifications and variations may be made without departing the spirit and scope of the present invention as defined by the appended claims. Further, such modifications and variations should not be understood independently from the technical idea or perspective of the present invention.

What is claimed is:

1. A solar cell module comprising:
a substrate; and
a transparent electrode layer,
wherein the transparent electrode layer includes:
a first electrode layer provided on the substrate; and
a second electrode layer provided on the first electrode layer, the first electrode layer and the second electrode layer being made of different materials and the second electrode layer being locally formed on portions of the first electrode layer.

2. The solar cell module according to claim 1, wherein the second electrode layer is formed of a plurality of islands on the first electrode layer, and portions of a top side of the first electrode layer are exposed between the plural islands.

3. The solar cell module according to claim 1, wherein the first electrode layer is made of tin oxide.

4. The solar cell module according to claim 1, wherein the second electrode layer is made of zinc oxide.

5. The solar cell module according to claim 2, wherein a distance between two neighboring islands among the plural islands ranges from 0.5 to 3 μm.

6. The solar cell module according to claim 1, wherein a thickness of the first electrode layer ranges from 100 to 800 nm.

7. The solar cell module according to claim 2, further comprising a protective layer provided on a top side of the first electrode layer exposed between the plural islands.

8. The solar cell module according to claim 7, wherein the protective layer is made of zinc oxide.

9. The solar cell module according to claim 1, further comprising a photoelectric conversion layer, a rear electrode layer, a seal film and a rear substrate sequentially arranged above the transparent electrode layer.

10. The solar cell module according to claim 1, wherein a top side of the first electrode layer is smooth and flat.

11. A method of fabricating a thin film solar cell module, the method comprising:
forming a transparent electrode layer on a substrate, wherein the forming of the transparent electrode layer includes:
providing a first electrode layer on the substrate;
providing a second electrode layer on the first electrode layer; and
etching the second electrode layer,
wherein the first electrode layer and the second electrode layer are formed using different materials, and
the second electrode layer is locally formed on portions of the first electrode layer by the etching.

12. The method according to claim 11, wherein the second electrode layer is formed of a plurality of islands, and portions of a top side of the first electrode layer are exposed between the plural islands.

13. The method according to claim 11, wherein the second electrode layer has a thickness of 100 to 800 nm.

14. The method according to claim 11, wherein the first electrode layer is formed of tin oxide.

15. The method according to claim 11, wherein the second electrode layer is formed of zinc oxide.

16. The method according to claim 11, wherein the etching is conducted by wet etching the second electrode layer using an acid.

17. The method according to claim 12, wherein a distance between two neighboring islands among the plural islands ranges from 0.5 to 3 μm.

18. The method according to claim 17, further comprising providing a protective layer on the top side of the first electrode layer exposed between the plural islands.

19. The method according to claim 11, further comprising providing a photoelectric conversion layer, a rear electrode layer, a seal film and a rear substrate sequentially above the transparent electrode layer.

20. The method according to claim 11, wherein a top side of the first electrode layer is smooth and flat.
